(19) United States
(12) Patent Application Publication
(10) Pub. No.: US 2022/0149330 A1
(43) Pub. Date: May 12, 2022

(54) METHOD FOR PRODUCING ORGANIC ELECTROLUMINESCENT DEVICE

(71) Applicant: SAKAI DISPLAY PRODUCTS CORPORATION, Sakai-shi, Osaka (JP)

(72) Inventor: KATSUHIKO KISHIMOTO, Sakai-shi, Osaka (JP)

(21) Appl. No.: 17/614,520

(22) PCT Filed: May 28, 2019
(86) PCT No.: PCT/JP2019/021129

§ 371 Date: Nov. 27, 2021

(51) Int. Cl. H01L 51/52; H01L 51/56; H01L 51/00

(52) U.S. Cl. CPC H01L 51/5253; H01L 51/0005; H01L 51/56

(57) ABSTRACT

A method for producing an organic electroluminescent device, includes the steps of forming the thin film encapsulation structure including: step A of forming a first inorganic barrier layer, step B of, after step A, detecting particles located below or above the first inorganic barrier layer and each having an area-equivalent diameter of 0.2 μm or longer and 5 μm or shorter, and finding position information, size information and shape information on each of the detected particles and finding an aspect ratio of each of particles, among the detected particles, having an area-equivalent diameter of 1 μm or longer, step C of supplying each of the particles with a microscopic liquid drop(s) of a coating liquid containing a photocurable resin by an inkjet method based on the position information, step D of, after step C, irradiating the photocurable resin with ultraviolet rays and thus curing the photocurable resin to form an organic barrier layer, and step E of, after step D, forming a second inorganic barrier layer on the first inorganic barrier layer and the organic barrier layer, and wherein step C includes the step of supplying each of first particles each having an aspect ratio of 3 or larger, among the particles, with a first microscopic liquid drop having a volume of 0.1 fL or larger and smaller than 10 fL at least twice along a longer axis of the first particle.

### TECHNICAL FIELD

The present invention relates to a method for producing an organic EL device (e.g., an organic EL display device and an organic EL illumination device).

### BACKGROUND ART

Organic EL (Electroluminescent) display devices start being put into practical use. One feature of an organic EL display device is flexibility thereof. Such an organic EL display device includes, in each of pixels, at least one organic EL element (Organic Light Emitting Diode: OLED) and at least one TFT (Thin Film Transistor) controlling an electric current to be supplied to each of the at least one OLED. Hereinafter, an organic EL display device will be referred to as an “OLED display device”. Such an OLED display device including a switching element such as a TFT or the like in each of OLEDs is called an “active matrix OLED display device”. A substrate including the TFTs and the OLEDs will be referred to as an “element substrate”.

An OLED (especially, an organic light emitting layer and a cathode electrode material) is easily influenced by moisture to be deteriorated and to cause display unevenness. One technology developed to provide an encapsulation structure that protects the OLED against moisture while not spoiling the flexibility of the OLED display device is a thin film encapsulation (TFE) technology. According to the thin film encapsulation technology, an inorganic barrier layer and an organic barrier layer are stacked alternately to allow such thin films to provide a sufficient level of water vapor barrier property. From the point of view of the moisture-resistance reliability of the OLED display device, such a thin film encapsulation structure is typically required to have a WVTR (Water Vapor Transmission Rate) lower than, or equal to, 1×10⁻⁴ g/m²/day.

A thin film encapsulation structure used in OLED display devices commercially available currently includes an organic barrier layer (polymer barrier layer) having a thickness of about 5 μm to about 20 μm. Such a relatively thick organic barrier layer also has a role of flattening a surface of the element substrate. However, such a thick organic barrier layer involves a problem of limiting the bendability of the OLED display device.

In such a situation, Patent Document No. 1 discloses a thin film encapsulation structure including a first inorganic material layer, a first resin member and a second inorganic material layer provided on the element substrate in this order, with the first inorganic barrier layer being closest to the element substrate. In this thin film encapsulation structure, the first resin member is present locally, more specifically, in the vicinity of a convex portion of the first inorganic material layer (first inorganic material layer covering a convex portion). According to Patent Document No. 1, since the first resin member is present locally, more specifically, in the vicinity of the convex portion, which may not be sufficiently covered with the first inorganic material layer, entrance of moisture or oxygen via the non-covered portion is suppressed. In addition, the first resin member acts as an underlying layer for the second inorganic material layer. Therefore, the second inorganic material layer is properly formed and properly covers a side surface of the first inorganic material layer with an expected thickness. The first resin member is formed as follows. An organic material heated and vaporized to be mist-like is supplied onto an element substrate maintained at a temperature lower than, or equal to, room temperature. The organic material is condensed and put into liquid drops on the substrate. The organic material in the liquid drops moves on the substrate by a capillary action or a surface tension to be present locally, more specifically, at a border between a side surface of the convex portion of the first inorganic material layer and a surface of the substrate. Then, the organic material is cured to form the first resin member at the border. Patent Document No. 2 also discloses an OLED display device including a similar thin film encapsulation structure.

The thin film encapsulation structure, described in Patent Document No. 1 or 2, that includes the organic barrier layer formed of a resin located locally does not include a thick organic barrier layer. Therefore, the thin film encapsulation structure is considered to improve the bendability of the OLED display device.

However, according to the studies made by the present inventor, an organic barrier layer formed by the method described in Patent Document No. 1 or 2 has a problem that a sufficiently high level of moisture-resistance reliability may not be provided. This problem has been found to be caused because water vapor in the air reaches the inside of an active region on the element substrate (the active region may also be referred to as an “element formation region” or a “display region”) via the organic barrier layer.

In the case where an organic barrier layer is formed by use of a printing method such as an inkjet method or the like, it is possible to form the organic barrier layer only in an active region on the element substrate (the active region may also be referred to as an “element formation region” or a “display region”) but not in a region other than the active region. In this case, along a periphery of the active region (outer to the active region), there is a region where the first inorganic material layer and the second inorganic material layer are in direct contact with each other, and the organic barrier layer is fully enclosed by the first inorganic material layer and the second inorganic material layer and is insulated from the outside of the first inorganic material layer and the second inorganic material layer.

By contrast, according to the method for forming the organic barrier layer described in Patent Document No. 1 or 2, a resin (organic material) is supplied to the entire surface of the element substrate, and the surface tension of the resin, which is in a liquid state, is used to locate the resin locally, more specifically, at the border between the surface of the element substrate and the side surface of the convex portion on the surface of the element substrate. Therefore, the organic barrier layer may also be formed in a region other than the active region (the region other than the active region may also be referred to as a “peripheral region”), namely, may also be formed in a terminal region where a plurality of terminals are located and a lead wire region where lead wires extending from the active region to the terminal region are formed. Specifically, the resin is present locally, more specifically, at, for example, the border between side surfaces of the lead wires or side surfaces of the terminals and the surface of the substrate. In this case, an end of a portion, of the organic barrier layer, that is formed along the lead wires is not enclosed by the first inorganic barrier layer or the second inorganic barrier layer, but is exposed to the air (ambient atmosphere).

The organic barrier layer is lower in the water vapor barrier property than the inorganic barrier layer. Therefore, the organic barrier layer formed along the lead wires acts as a route that leads the water vapor in the air into the active region.

As can be seen, the method for forming the organic barrier layer described in Patent Document No. 1 or 2 merely uses the surface tension of the resin in a liquid state to locate the organic barrier layer locally. Therefore, there is an undesirable possibility that the organic barrier layer is formed in a region where the organic barrier layer does not need to be formed, or that by contrast, the organic barrier layer is not guaranteed to be formed in a region where the organic barrier layer needs to be formed.

Patent Document No. 3 discloses a method for supplying a precursor (photocurable resin) for an organic barrier layer to each of particles by an inkjet method.

### CITATION LIST

### Patent Literature

Patent Document No. 1: WO2014/196137
Patent Document No. 2: Japanese Laid-Open Patent Publication No. 2016-39120
Patent Document No. 3: United States Patent Application Publication No. 2014/0049923

### SUMMARY OF INVENTION

### Technical Problem

However, the method for forming an organic barrier layer by use of the inkjet method described in Patent Document No. 3 may undesirably not provide a sufficient level of moisture-resistance reliability. A reason for this is that with the method described in Patent Document No. 3, the particles provided with the precursors by the inkjet method are limited to relatively large particles having a width exceeding 3 μm (particle 310 in FIG. 6). According to the studies made by the present inventor, the moisture-resistance reliability is declined even with a relatively small particle having a width of 3 μm or shorter. In the case where the particle is small or in the case where the particle is lengthy, the precursors are supplied in an excessive amount, and as a result, an unnecessarily thick organic barrier layer is formed. This may cause local display unevenness and thus deteriorate the display quality.

In the above, some problems of a thin film encapsulation structure preferably usable for a flexible organic EL display device are described. The thin film encapsulation structure is not limited to being used for an organic EL display device, and is also usable for other types of organic EL devices such as an organic EL illumination device and the like. The organic EL illumination device may also involve the problem that the moisture-resistance reliability is declined or that the luminous intensity distribution characteristics are declined due to uneven luminance.

The present invention, made to solve the above-described problems, has an object of providing a method for producing an organic EL device that includes a thin film encapsulation structure improved in the moisture-resistance reliability and/or the display characteristics and the luminous intensity distribution characteristics, by forming an appropriate organic barrier layer even for a relatively small particle or a lengthy particle.

### Solution to Problem

An embodiment of the present invention provides the solution to the problem defined by the following items.

[Item 1]

A method for producing an organic EL device, comprising the steps of:

preparing an element substrate including a substrate and a plurality of organic EL elements supported by the substrate; and

forming a thin film encapsulation structure covering the plurality of organic EL elements,

wherein the step of forming the thin film encapsulation structure includes:
step A of forming a first inorganic barrier layer,
step B of, after the step A, detecting particles located below or above the first inorganic barrier layer and each having an area-equivalent diameter of 0.2 μm or longer and 5 μm or shorter, and finding position information, size information and shape information on each of the detected particles and finding an aspect ratio of each of particles, among the detected particles, having an area-equivalent diameter of 1 μm or longer,
step C of supplying each of the particles with a microscopic liquid drop(s) of a coating liquid containing a photocurable resin by an inkjet method based on the position information,
step D of, after the step C, irradiating the photocurable resin with ultraviolet rays and thus curing the photocurable resin to form an organic barrier layer, and
step E of, after the step D, forming a second inorganic barrier layer on the first inorganic barrier layer and the organic barrier layer, and

wherein the step C includes the step of supplying each of first particles each having an aspect ratio of 3 or larger, among the particles, with a first microscopic liquid drop having a volume of 0.1 fL or larger and smaller than 10 fL at least twice along a longer axis of the first particle.

Such first microscopic liquid drops may be supplied generally on the longer axis of the particle or generally on a contour of the particle along the longer axis of the particle.

[Item 2]

A method for producing an organic EL device, comprising the steps of:

preparing an element substrate including a substrate and a plurality of organic EL elements supported by the substrate; and

forming a thin film encapsulation structure covering the plurality of organic EL elements,

wherein the step of forming the thin film encapsulation structure includes:
step A of forming a first inorganic barrier layer,
step B of, after the step A, detecting particles located below or above the first inorganic barrier layer and each having an area-equivalent diameter of 0.2 μm or longer and 5 μm or shorter, and finding position information, size information and shape information on each of the detected particles and finding an aspect ratio of each of particles, among the detected particles, having an area-equivalent diameter of 1 μm or longer,
step C of supplying each of the particles with a microscopic liquid drop(s) of a coating liquid containing a photocurable resin by an inkjet method based on the position information,
step D of, after the step C, irradiating the photocurable resin with ultraviolet rays and thus curing the photocurable resin to form an organic barrier layer, and
step E of, after the step D, forming a second inorganic barrier layer on the first inorganic barrier layer and the organic barrier layer, and

wherein the step C includes the step of supplying each of first particles each having an aspect ratio of 3 or larger, among the particles, with a first microscopic liquid drop having a volume of 0.1 fL or larger and smaller than 10 fL and having a diameter shorter than a length of a longer axis of the first particle.

[Item 3]

The method of item 1 or 2, wherein in the step C, the microscopic liquid drops include a second microscopic liquid drop having a size larger than that of the first microscopic liquid drop; and the step C includes the step of selecting the first microscopic liquid drop for the first particle, and selecting the second microscopic liquid drop for, among second particles each having an aspect ratio smaller than 2, at least each of particles having an area-equivalent diameter of 5 μm, based on the size information on each of the particles.

[Item 4]

The method of item 3, wherein the first microscopic liquid drop does not contain a dye or a pigment, and the second microscopic liquid drop contains a dye or a pigment.

[Item 5]

The method of item 3 or 4, wherein the second microscopic liquid drop has a volume of 10 fL or larger and 0.5 pL or smaller.

[Item 6]

The method of any one of items 1 through 5, wherein the first microscopic liquid drop has a volume of 1 fL or smaller.

[Item 7]

The method of any one of items 1 through 6, wherein the step D includes the step of partially ashing a photocured resin layer formed by curing the photocurable resin.

[Item 3]

The method of any one of items 1 through 7, further comprising the step of, before the step C, ashing a surface of the first inorganic barrier layer.

### Advantageous Effects of Invention

An embodiment according to the present invention provides a method for producing an organic EL device that includes a thin film encapsulation structure including a relatively thin organic barrier layer improved in the moisture-resistance reliability and/or the display characteristics and the luminous intensity distribution characteristics.

### BRIEF DESCRIPTION OF DRAWINGS

FIG. 1(a) is a schematic partial cross-sectional view of an active region of an OLED display device 100 according to an embodiment of the present invention, and FIG. 1(b) is a partial cross-sectional view of a TFE structure 10 formed on an OLED 3.

FIG. 2 is a plan view schematically showing a structure of the OLED display device 100 according to an embodiment of the present invention.

FIG. 3(a) through FIG. 3(d) are each a schematic cross-sectional view of the OLED display device 100; FIG. 3(a) is a cross-sectional view taken along line 3A-3A′ in FIG. 2, FIG. 3(b) is a cross-sectional view taken along line 3B-3B′ in FIG. 2, FIG. 3(c) is a cross-sectional view taken along line 3C-3C′ in FIG. 2, and FIG. 3(d) is a cross-sectional view taken along line 3D-3D′ in FIG. 2.

FIG. 4(a) is an enlarged view of a portion including a particle P shown in FIG. 3(a), FIG. 4(b) is a schematic plan view showing the size relationship among the particle P, a first inorganic barrier layer (SiN layer) covering the particle P, and an organic barrier layer, and FIG. 4(c) is a schematic cross-sectional view of the first inorganic barrier layer covering the particle P.

FIG. 5 is a schematic view showing a foreign object detection device 40 usable for a method for producing an OLED display device according to an embodiment of the present invention.

FIG. 6 is a schematic view showing an inkjet device 50 usable for a method for producing an OLED display device according to an embodiment of the present invention.

FIG. 7 shows schematic views provided to describe a preferred range of volume of an organic barrier layer to be formed in the vicinity of the particle P in an OLED display device according to an embodiment of the present invention; FIG. 7(a) is a schematic view of a cross-section including a diameter of the particle P (cross-section taken along line 7A-7A′ in FIG. 7(b)), and FIG. 7(b) is a plan view as seen in the normal direction.

FIG. 8 shows SEM images of particles viewed during the production of an OLED display device; FIG. 8(a) is an SEM image viewed from just above, in which particles are recognized in circles, FIG. 8(b) is a perspective SEM image of grain-like particles, and FIG. 8(c) is a cross-sectional SEM image of a portion including a particle buried in a resin layer.

FIG. 9 is a schematic plan view of a lengthy particle Pi.

FIG. 10 shows schematic views of a state where the lengthy particle Pi is supplied with a microscopic liquid drop 14D having a diameter longer than a length of a longer axis of the lengthy particle Pi; FIG. 10(a) is a plan view thereof, and FIG. 10(b) is a side view thereof.

FIG. 11 shows schematic views of a state where the lengthy particle Pi is supplied with four microscopic liquid drops 14Ds by an inkjet method by a method for producing an OLED display device according to an embodiment of the present invention;

FIG. 11(a) is a plan view thereof, and FIG. 11(b) is a side view thereof.

FIG. 12 shows schematic views of another state where the lengthy particle Pi is supplied with microscopic liquid drops 14Ds by the inkjet method by a method for producing an OLED display device according to an embodiment of the present invention; FIG. 12(a) is a plan view thereof, and FIG. 12(b) is a side view thereof.

### DESCRIPTION OF EMBODIMENTS

Hereinafter, a method for producing an organic EL device according to an embodiment of the present invention, and an organic EL device produced by the production method, will be described with reference to the drawings. Hereinafter, an OLED display device will be described as an example of the organic EL device. Embodiments according to the present invention are not limited to the embodiments described below as examples.

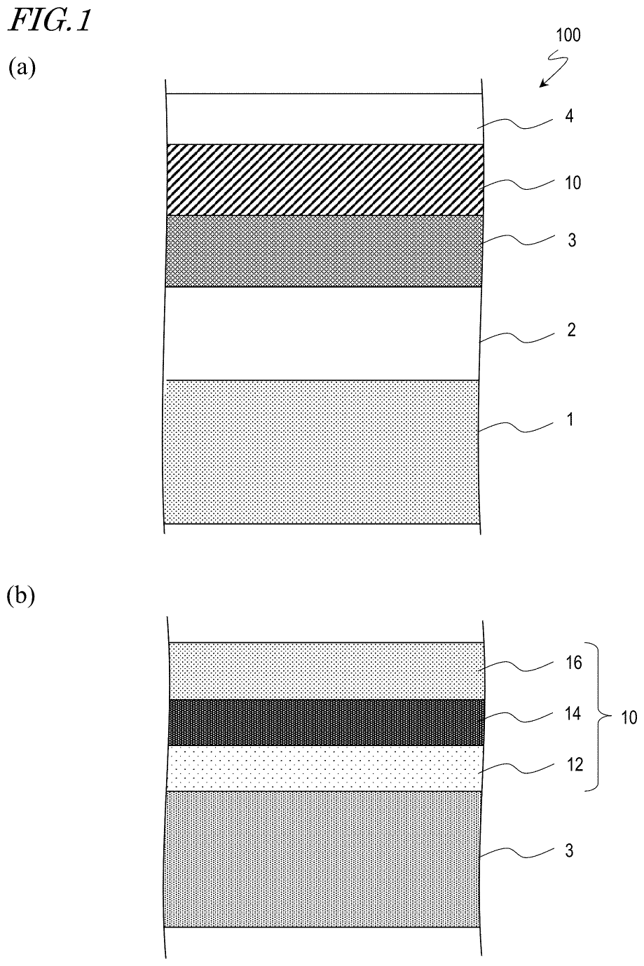

First, with reference to FIG. 1(a) and FIG. 1(b), a basic structure of an OLED display device 100 produced by a production method according to an embodiment of the present invention will be described. FIG. 1(a) is a schematic partial cross-sectional view of an active region of the OLED display device 100 according to an embodiment of the present invention. FIG. 1(b) is a partial cross-sectional view of a TFE structure 10 formed on an OLED 3.

The OLED display device 100 includes a plurality of pixels, and each of the pixels includes at least one organic EL element (OLED). Herein, a structure corresponding to one OLED will be described for the sake of simplicity.

As shown in FIG. 1(a), the OLED display device 100 includes a flexible substrate (hereinafter, may be referred to simply as a “substrate”) 1, a circuit (back plane) 2 formed on the substrate 1 and including a TFT, the OLED 3 formed on the circuit 2, and the TFE structure 10 formed on the OLED 3. The OLED 3 is, for example, of a top emission type. An uppermost portion of the OLED 3 is, for example, an upper electrode or a cap layer (refractive index adjusting layer). An optional polarizing plate 4 is located on the TFE structure 10.

The substrate 1 is, for example, a polyimide film having a thickness of 15 μm. The circuit 2 including the TFT has a thickness of, for example, 4 μm. The OLED 3 has a thickness of, for example, 1 μm. The TFE structure 10 has a thickness, for example, less than, or equal to, 1.5 μm.

FIG. 1(b) is a partial cross-sectional view of the TFE structure 10 formed on the OLED 3. A first inorganic barrier layer (e.g., SiN layer) 12 is formed immediately on the OLED 3, an organic barrier layer (e.g., photocured resin layer) 14 is formed on the first inorganic barrier layer 12, and a second inorganic barrier layer (e.g., SiN layer) 16 is formed on the organic barrier layer 14.

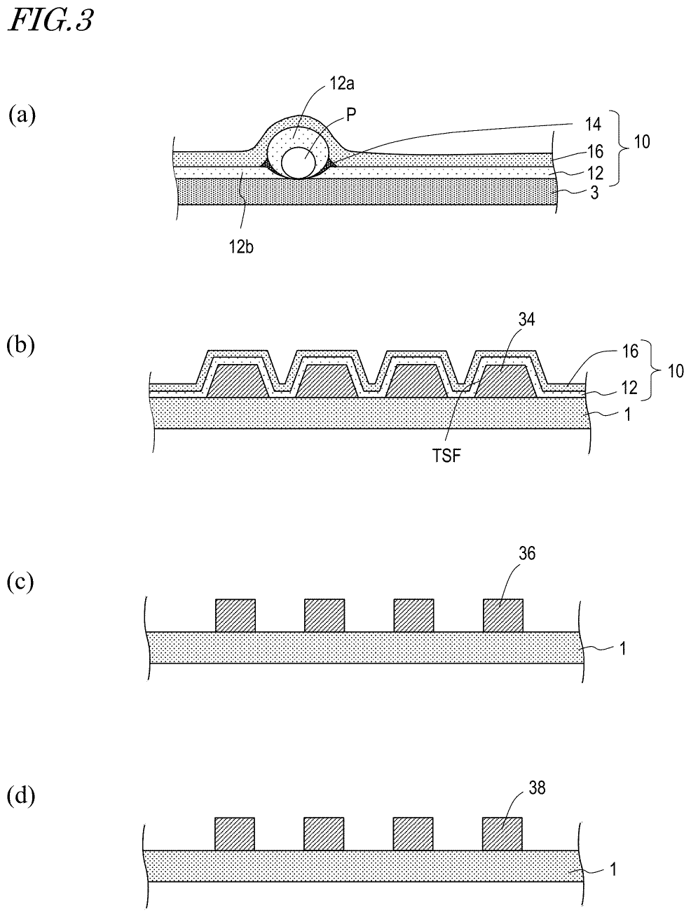

As described below, the organic barrier layer 14 is formed only in a discontinuous portion, of the first inorganic barrier layer 12, that is formed on a particle (microscopic dust particle) (see, for example, FIG. 3(a)), or is formed only in a discontinuous portion at a border between the first inorganic barrier layer 12 and the particle present on the first inorganic barrier layer 12.

The first inorganic barrier layer 12 and the second inorganic barrier layer 16 are each, for example, an SiN layer having a thickness of, for example, 400 nm. The first inorganic barrier layer 12 and the second inorganic barrier layer 16 each have a thickness of 200 nm or greater and 1000 nm or less independently. The thickness of the TFE structure 10 is preferably 400 nm or greater and less than 2 μm, and more preferably 400 nm or greater and less than 1.5 μm. The thickness of the organic barrier layer 14, which depends on the size of the particle, is generally 50 nm or greater and less than 200 nm.

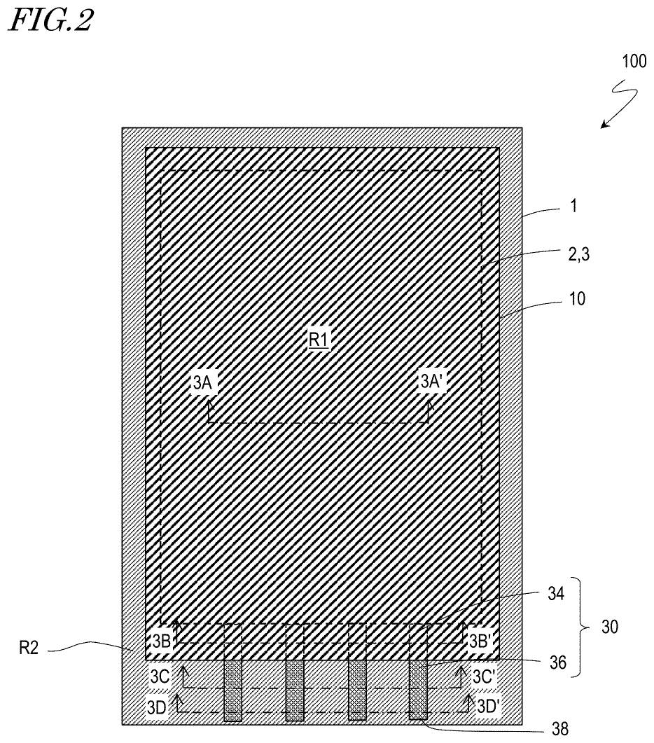

The TFE structure 10 is formed so as to protect the active region (see the active region R1 in FIG. 2) of the OLED display device 100. As described above, the TFE structure 10 includes, in at least the active region, the first inorganic barrier layer 12, the organic barrier layer 14 and the second inorganic barrier layer 16 in this order, with the first inorganic barrier layer 12 being closest to the OLED 3. The organic barrier layer (solid portion) 14 is formed only in a discontinuous portion formed by the particle, and the first inorganic barrier layer 12 and the second inorganic barrier layer 16 are in direct contact with each other in the remaining portion. Therefore, the active region is mostly a portion where the first inorganic barrier layer 12 and the second inorganic barrier layer 16 are in direct contact with each other (hereinafter, such a portion may be referred to as an “inorganic barrier layer joint portion”), and the organic barrier layer 14 does not act as a route that leads water vapor in the air into the active region.

With reference to FIG. 2 through FIG. 7, a method for producing an OLED display device according to an embodiment of the present invention, and an OLED display device produced by such a production method, will be described.

FIG. 2 is a schematic plan view of the OLED display device 100 according to an embodiment of the present invention.

The OLED display device 100 includes the flexible substrate 1, the circuit (back plane) 2 formed on the substrate 1, a plurality of the OLEDs 3 formed on the circuit 2, and the TFE structure 10 formed on the OLEDs 3. A layer including the plurality of OLEDs 3 may be referred to as an “OLED layer 3”. The circuit 2 and the OLED layer 3 may share a part of components. The optional polarizing plate (see reference sign 4 in FIG. 1) may further be located on the TFE structure 10. In addition, for example, a layer having a touch panel function may be located between the TFE structure 10 and the polarizing plate. Namely, the OLED display device 100 may be altered to a display device including an on-cell type touch panel.

The circuit 2 includes a plurality of TFTs (not shown), and a plurality of gate bus lines (not shown) and a plurality of source bus lines (not shown) each connected with either one of the plurality of TFTs (not shown). The circuit 2 may be a known circuit that drives the plurality of OLEDs 3. The plurality of OLEDs 3 are each connected with either one of the plurality of TFTs included in the circuit 2. The OLEDs 3 may be known OLEDs.

The OLED display device 100 further includes a plurality of terminal portions 38 located in a peripheral region R2 outer to the active region R1 (region enclosed by the dashed line in FIG. 2), where the plurality of OLEDs 3 are located, and also includes a plurality of lead wires 30 connecting each of the plurality of terminal portions 38 and either one of the plurality of gate bus lines or either one of the plurality of source bus lines to each other. The TFE structure 10 is formed on the plurality of OLEDs 3 and on portions, of the plurality of lead wires 30, that are closer to the active region R1. Namely, the TFE structure 10 covers the entirety of the active region R1 and is also selectively formed on the portions, of the plurality of lead wires 30, that are closer to the active region R1. Neither portions, of the plurality of lead wires 30, that are closer to the terminal portions 38, nor the terminal portions 38, are covered with the TFE structure 10.

Hereinafter, an example in which the lead wires 30 and the terminal portions 38 are integrally formed in the same conductive layer will be described. Alternatively, the lead wires 30 and the terminal portions 38 may be formed in different conductive layers (encompassing stack structures).

Now, with reference to FIG. 3(a) through FIG. 3(d), the TFE structure 10 of the OLED display device 100 will be described. FIG. 3(a) is a cross-sectional view taken along line 3A-3A′ in FIG. 2. FIG. 3(b) is a cross-sectional view taken along line 3B-3B′ in FIG. 2. FIG. 3(c) is a cross-sectional view taken along line 3C-3C′ in FIG. 2. FIG. 3(d) is a cross-sectional view taken along line 3D-3D′ in FIG. 2.

As shown in FIG. 3(a) and FIG. 3(b), the TFE structure 10 includes the first inorganic barrier layer 12 formed on the OLED 3, the organic barrier layer 14, and the second inorganic barrier layer 16 in contact with the first inorganic barrier layer 12 and the organic barrier layer 14. The first inorganic barrier layer 12 and the second inorganic barrier layer 16 are each, for example, an SiN layer, and are selectively formed only in a predetermined region so as to cover the active region R1 by plasma CVD by use of a mask. The organic barrier layer (solid portion) 14 is formed by an inkjet method only in a discontinuous portion formed by the particle.

FIG. 3(a) is a cross-sectional view taken along line 3A-3A′ in FIG. 2, and shows a portion including a particle P. The particle P is a microscopic dust particle generated during the production of the OLED display device, and is, for example, a microscopic piece of broken glass, a metal particle or an organic particle. Such a particle P is especially easily generated in the case where mask vapor deposition is used.

As shown in, for example, FIG. 3(a), the organic barrier layer 14 is formed only in a discontinuous portion formed by the particle P. Namely, the organic barrier layer 14 is not present in a region where the particle P is not present, and the OLED display device including no particle P does not include the organic barrier layer. A particle P having a size (represented by, for example, a volume-equivalent diameter or an area-equivalent diameter) of approximately 0.3 μm or longer and 5 μm or shorter declines the moisture-resistance reliability of the TFE structure 10. The “volume-equivalent diameter” refers to a diameter of a sphere having a volume equal to that of the particle, and the “area-equivalent diameter” refers to a diameter of a circle having an area size equal to that of a graphical shape obtained by the particle being projected on a plane (equal to the projected area size). In the case where the particle is spherical, the volume-equivalent diameter and the area-equivalent diameter are equal to each other.

A particle having an area-equivalent diameter (or a volume-equivalent diameter; this will also apply to the following description) longer than 3 μm as described in Patent Document No. 3, and also a particle having a volume-equivalent diameter of 0.3 μm or longer and 3 μm or shorter, may also decline the moisture-resistance reliability. In addition, a particle P having a size of 0.2 μm or longer and shorter than 0.3 μm may also decline the moisture-resistance reliability, undesirably. A particle P having a size shorter than 0.2 μm is considered to have substantially no possibility of declining the moisture-resistance reliability. A particle having a size longer than 5 μm is removed by cleaning or the like.

One substrate of G4.5 (730 mm×920 mm) may include, for example, several tens to about 100 particles each having a size of approximately 0.3 μm or longer and 5 μm or shorter. One OLED display device (active region) may include approximately several particles. Needless to say, there are OLED display devices with no particle P. The organic barrier layer 14 is formed of, for example, a photocured resin formed by curing a photocurable resin. A portion where the photocured resin is actually present is referred to as a “solid portion”. The organic barrier layer 14 includes at least one solid portion, and may include two or more solid portions.

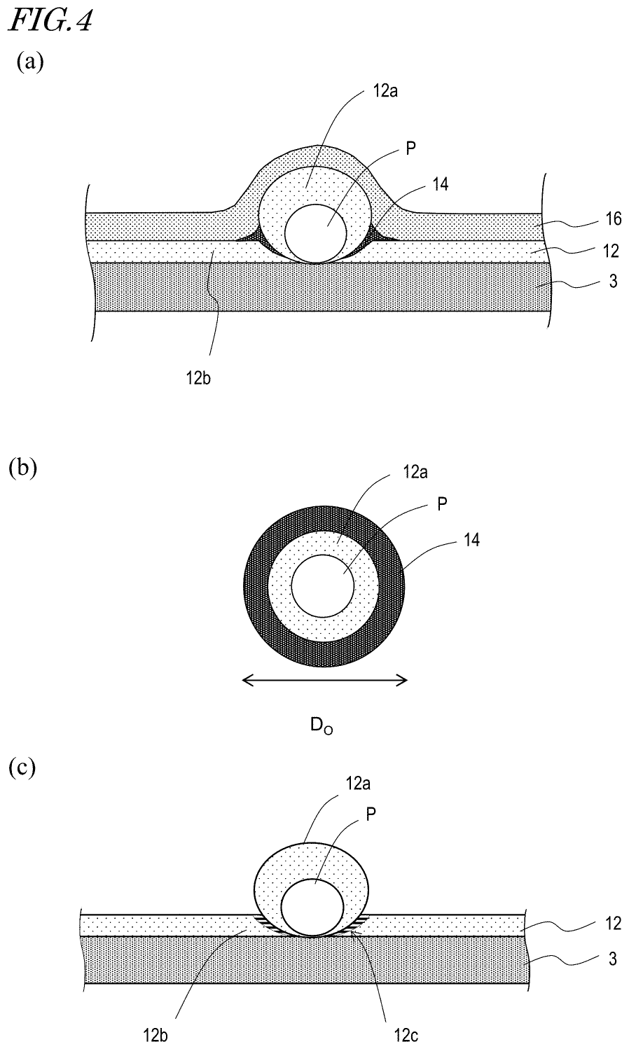

Now, with reference to FIG. 4(a) through FIG. 4(c), a structure of the portion including the particle P will be described. FIG. 4(a) is an enlarged view of the portion including the particle P shown in FIG. 3(a). FIG. 4(b) is a schematic plan view showing the size relationship among the particle P, the first inorganic barrier layer (SiN layer) covering the particle P and the organic barrier layer. FIG. 4(c) is a schematic cross-sectional view of the first inorganic barrier layer covering the particle P.

In the TFE structure 10 of the OLED display device 100, as shown in FIG. 4(a), the organic barrier layer 14 is formed to fill a crack 12c of the first inorganic barrier layer 12, and a surface (concave surface) of the organic barrier layer 14 couples a surface of a first inorganic barrier layer 12a on the particle P and a surface of a first inorganic barrier layer 12b on a flat portion of the OLED 3 to each other continuously and smoothly. The organic barrier layer 14, which is formed by curing a photocurable resin in a liquid state as described below, has a concave surface formed by a surface tension. In this state, the photocurable resin exhibits a high level of wettability to the first inorganic barrier layer 12. If the level of wettability of the photocurable resin to the first inorganic barrier layer 12 is low, the surface of the organic barrier layer 14 may protrude. In this case, the second inorganic barrier layer 16 formed on the organic barrier layer 14 may be cracked, which is not preferred. The organic barrier layer 14 may also be formed with a small thickness on the surface of the first inorganic barrier layer 12a on the particle P.

The organic barrier layer (solid portion) 14 having the concave surface couples the surface of the first inorganic barrier layer 12a on the particle P and the surface of the first inorganic barrier layer 12b on the flat portion to each other continuously and smoothly. Therefore, the second inorganic barrier layer 16 formed thereon is a fine film with no defect. As can be seen, even if the particle P is present, the organic barrier layer 14 keeps high the level of barrier property of the TFE structure 10.

As shown in FIG. 4(b), the organic barrier layer (solid portion) 14 is formed in a ring shape around the particle P. Where the particle P has a diameter (area-equivalent diameter) of about 1 μm as seen in a direction normal to the surface of the OLED 3, the ring-shaped solid portion has a diameter (area-equivalent diameter) Do that is, for example, longer than, or equal to, 2 μm.

In this example, the organic barrier layer 14 is formed only in a discontinuous portion, of the first inorganic barrier layer 12, that is formed on the particle P, and the particle P is already present before the first inorganic barrier layer 12 is formed on the OLED 3. Alternatively, the particle P may be present on the first inorganic barrier layer 12. In this case, the organic barrier layer 14 is formed only at the border, namely, in a discontinuous portion, between the first inorganic barrier layer 12 and the particle P present on the first inorganic barrier layer 12, and thus maintains the barrier property of the TFE structure 10 like in the above-described case. The organic barrier layer 14 may also be formed with a small thickness on the surface of the first inorganic barrier layer 12a on the particle P, or on the surface of the particle P. In this specification, the expression that “the organic barrier layer (solid portion) 14 is present in the vicinity of the particle P” encompasses all these forms.

Now, with reference to FIG. 3(b), a structure of the TFE structure 10 on the lead wires 30 will be described. FIG. 3(b) is a cross-sectional view taken along line 3B-3B′ in FIG. 2; more specifically, is a cross-sectional view of portions 34, of the lead wires 30, closer to the active region R1. Still more specifically, FIG. 3(b) is a cross-sectional view of the portions 34, each of which has a forward tapering side surface portion (inclining side surface portion) TSF having a tapering angle smaller than 90 degrees.

The lead wires 30 are patterned by the same process as that of, for example, the gate bus lines or the source bus lines. Thus, in this example, the gate bus lines and the source bus lines formed in the active region R1 also have the same cross-sectional structure as that of the portion 34, of each of the lead wires 30, closer to the active region R1. The cross-sectional structure of the portions 34 is shown in FIG. 3(b).

The active region R1 of the OLED display device 100 is substantially covered with the inorganic barrier layer joint portion, where the first inorganic barrier layer 12 and the second inorganic barrier layer 16 are in direct contact with each other, except for the portion in the vicinity of the particle P, namely, the portion where the organic barrier layer 14 is selectively formed. Therefore, it does not occur that the organic barrier layer 14 acts as an entrance route for moisture and allows the moisture to reach the active region R1 of the OLED display device.

In the case where the lead wire 30 includes the forward tapering side surface portion TSF, formation of defects in the first inorganic barrier layer 12 and the second inorganic barrier layer 16 formed on the lead wire 30 is prevented. Namely, the moisture-resistance reliability of the TFE structure 10 is improved. The tapering angle of the forward tapering side surface portion TSF is preferably smaller than, or equal to, 70 degrees.

The OLED display device 100 according to an embodiment of the present invention is preferably usable for, for example, medium- to small-sized high-definition smartphones and tablet terminals. In a medium- to small-sized (e.g., 5.7-inch) high-definition (e.g., 500 ppi) OLED display device, it is preferred that lines (encompassing the gate bus lines and the source bus lines) in the active region R1 have a cross-sectional shape, taken in a direction parallel to a line width direction, close to a rectangle (side surfaces of the lines have a tapering angle of about 90 degrees) in order to allow the lines to have a sufficiently low resistance with a limited line width. In order to form the lines having a low resistance, the tapering angle of the forward tapering side surface portion TSF may be larger than 70 degrees and smaller than 90 degrees, or the tapering angle may be about 90 degrees in the entire length of the lines with no forward tapering side surface portion TSF being supplied as long as no defect is formed in the first inorganic barrier layer 12 or the second inorganic barrier layer 16.

Now, FIG. 3(c) and FIG. 3(d) will be referred to. FIG. 3(c) and FIG. 3(d) are each a cross-sectional view of a region where the TFE structure 10 is not formed. Neither portions 36 of the lead wires 30 shown in FIG. 3(c) nor the terminal portions 38 shown in FIG. 3(d) need to include a forward tapering side surface portion TSF, and therefore, may have a tapering angle of about 90 degrees as shown in the figures.

The organic barrier layer (solid portion) 14 included in the OLED display device 100 according to an embodiment of the present invention is formed only in the vicinity of the particle P by an inkjet method. Therefore, no resin is present locally, more specifically, at a border between the side surfaces of the lead wires or the side surfaces of the terminal portions and the surface of the substrate. For this reason, even if the tapering angle is about 90 degrees, the organic barrier layer (solid portion) 14 is not formed along the lead wires, and the moisture-resistance reliability is not declined by the formation of the organic barrier layer (solid portion) 14.

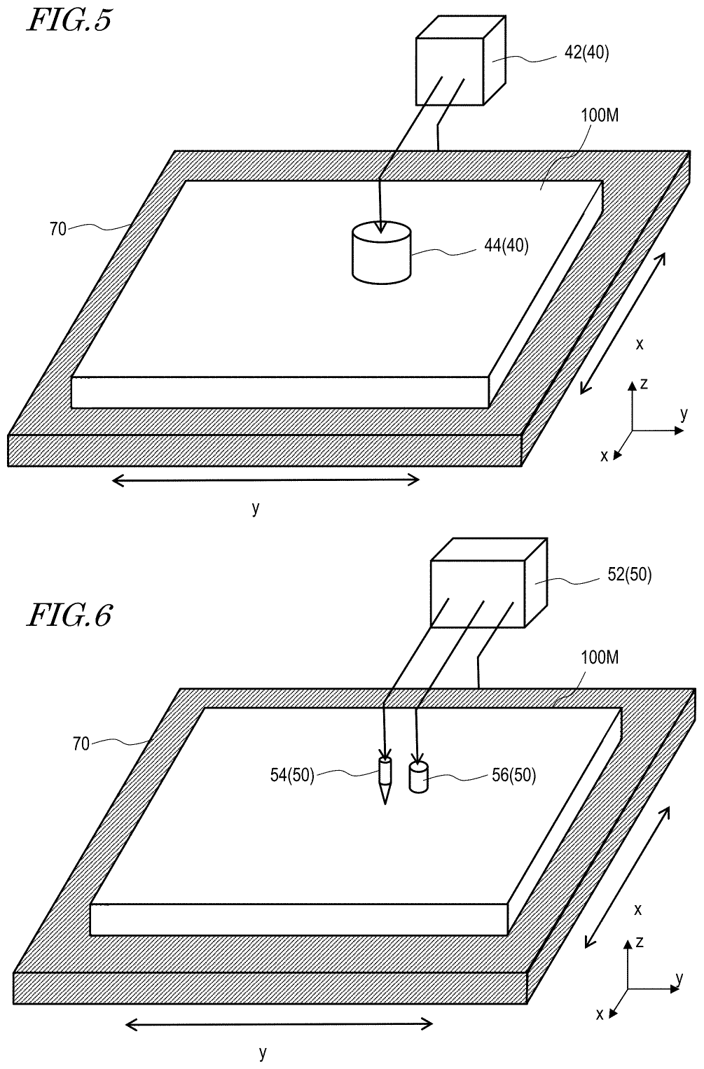

Now, with reference to FIG. 5 and FIG. 6, a method for producing an OLED display device according to an embodiment of the present invention will be described.

A method for producing an OLED display device according to an embodiment of the present invention includes a step of preparing an element substrate including a substrate and a plurality of organic EL elements supported by the substrate, and a step of forming a thin film encapsulation structure covering the plurality of organic EL elements. The step of forming the thin film encapsulation structure includes step A of forming a first inorganic barrier layer; step B of, after the step A, detecting particles located below or above the first inorganic barrier layer and each having an area-equivalent diameter of 0.3 μm or longer and shorter than 3 μm, and particles located below or above the first inorganic barrier layer and each having an area-equivalent diameter of 3 μm or longer and 5 μm or shorter, to find position information on each of the particles; step C of supplying each of the particles with a microscopic liquid drop(s) of a coating liquid containing a photocurable resin by an inkjet method based on the found position information; step D of, after the step C, irradiating the photocurable resin with ultraviolet rays and thus curing the photocurable resin to form an organic barrier layer; and step E of, after the step D, forming a second inorganic barrier layer on the first inorganic barrier layer and the organic barrier layer. The particles detected in the step B may include particles each having an area-equivalent diameter of 0.2 μm or longer and 0.3 μm or shorter. The method for producing an OLED display device according to this embodiment includes a foreign object detection step (the step B) and an inkjet step (the step C). This allows the OLED display device having the above-described structure to be produced.

FIG. 5 is a schematic view showing a foreign object detection device 40 usable for the method for producing an OLED display device according to an embodiment of the present invention. FIG. 6 is a schematic view showing an inkjet device 50 usable for the method for producing an OLED display device according to an embodiment of the present invention.

The foreign object detection device 40 shown in FIG. 5 includes a controller 42 and a detection head 44. The controller 42 controls an operation of the detection head 44 and also controls an operation of a stage 70. The stage 70 is capable of receiving a substrate 100M and transporting the substrate 100M in an x-axis direction and a y-axis direction. The stage 70 is capable of, for example, attracting and securing the substrate 100M, and/or transporting the substrate 100M in a floating state (contactless transportation). The substrate 100M is, for example, an element substrate formed by use of a G4.5 mother substrate, and includes the components up to the first inorganic barrier layer.

The controller 42 includes a memory and a processor (neither is shown), and controls the detection head 44 and/or the stage 70 to operate in accordance with information stored on the memory, so that the detection head 44 scans on the substrate 100M. A signal that controls the detection head 44 and/or the stage 70 to operate is generated by the processor and supplied to the detection head 44 and/or the stage 70 via an interface (represented by the arrow in the figure).

The detection head 44 includes, for example, a laser light source (e.g., semiconductor laser element), an image-forming optical system, and an image sensor (none of these components is shown). Laser light is directed toward a predetermined position on the substrate 100M, and the light scattered by the substrate 100M is caused, by the image-forming optical system, to form an image on a light receiving surface of the image sensor. Based on the result of image-capturing performed by the image sensor, the processor finds whether or not there is a particle, as well as position information, size information, shape information and the like on the particle, in accordance with a predetermined algorithm, and stores the obtained results on the memory. Such a foreign object detection device is described in, for example, Japanese Laid-Open Patent Publication No. 2016-105052. The entirety of the disclosure of Japanese Laid-Open Patent Publication No. 2016-105052 is incorporated herein by reference. As the foreign object detection device 40, for example, HS-930 produced by Toray Engineering Co., Ltd. is preferably usable. HS-930 is capable of detecting a foreign object having a size of 0.3 μm (evaluation performed by scattering standard particles). HS-930 is capable of inspecting, for example, a G4.5 substrate in a time period shorter than 60 seconds.

The standard particle is a true sphere polystyrene latex particle. By contrast, the actual particle P is a microscopic piece of broken glass, a metal particle or an organic particle (organic EL material), and is covered with an SiN layer (refractive index: about 1.8; second inorganic barrier layer). Therefore, the actual particle P is more easily detectable than the standard particle. With the above-described foreign object detection device using scattered laser light, a foreign object having an area-equivalent diameter of 0.2 μm or longer is detected.

The inkjet device 50 shown in FIG. 6 includes a controller 52, an inkjet head 54, and a UV (ultraviolet) irradiation head 56.

The controller 52 includes a memory and a processor (neither is shown), and controls the inkjet head 54, the irradiation head 56 and/or the stage 70 to operate in accordance with information stored on the memory, so that the inkjet head 54 and the UV irradiation head 56 move to a desired position on the substrate 100M.

A signal that controls the inkjet head 54, the UV irradiation head 56 and/or the stage 70 to operate is generated by the processor and supplied to the inkjet head 54, the UV irradiation head 56 and/or the stage 70 via interfaces (represented by the arrows in the figure). For example, position information (e.g., xy coordinates), on the position at which the particle is present, stored on the memory of the controller 42 of the foreign object detection device 40 is received by the controller 52. Based on the position information, microscopic liquid drops of the coating liquid containing the photocurable resin are supplied from the inkjet head 54. The amount of the coating liquid (the number of the microscopic liquid drops, namely, the number of shots) supplied from the inkjet head 54 is, for example, found by the processor based on position information, size information, shape information and the like on the particle stored on the memory of the controller 42 of the foreign object detection device 40 and received by the controller 52.

Then, the UV irradiation head 56 irradiates the supplied photocurable resin with ultraviolet rays and thus cures the photocurable resin to form the organic barrier layer. The above-described operation is performed on each of the particles.

FIG. 6 shows the inkjet head 54 and the UV irradiation head 56 as being separate from each other. Alternatively, the inkjet head 54 and the UV irradiation head 56 may be supplied as one head. An LED or a semiconductor laser element may be used as an ultraviolet light source, so that the UV irradiation head 56 is realized as a compact device including a light source itself. Alternatively, the UV irradiation device 56 may include only an output end of an optical fiber and a lens unit supplied when necessary. In this case, as an ultraviolet light source unit that emits ultraviolet rays toward an incident end of the optical fiber, a semiconductor laser element, an LED, or any of various other ultraviolet light sources (e.g., lamps such as, for example, a mercury xenon lamp, a super-high pressure mercury lamp, and the like) is usable. In consideration of the coupling efficiency, it is preferred to use a light source capable of oscillating laser light, for example, a semiconductor laser element or the like. The light source may be an LED. In the case where the UV irradiation head 56 and an ultraviolet light source are located separately from each other as in the above-described example, there is an advantage that in a series of steps including the detection of a foreign object, the supply of a coating liquid and the irradiation with ultraviolet rays, the influence exerted by heat generation of the light source on the OLED 3 in the substrate 100M is decreased. Alternatively, for example, a plurality of inkjet heads may be prepared. For example, two or more inkjet heads generating microscopic liquid drops of different sizes may be prepared, so that different inkjet heads are used for particles of different sizes.

For example, the inkjet head 54 preferably usable may generate microscopic liquid drops each having a volume of the order of 1 fL (1 fL or larger and smaller than 10 fL) or may generate microscopic liquid drops each having a volume smaller than 1 fL. 1 fL corresponds to a volume of a sphere having a diameter of about 1.2 μm, and 0.1 fL corresponds to a volume of a sphere having a diameter of about 0.6 μm. For example, the inkjet device, produced by SIJ Technology Inc., that is capable of injecting 0.1 fL microscopic liquid drops (specifically, Super Inkjet (registered trademark)) is preferably usable.

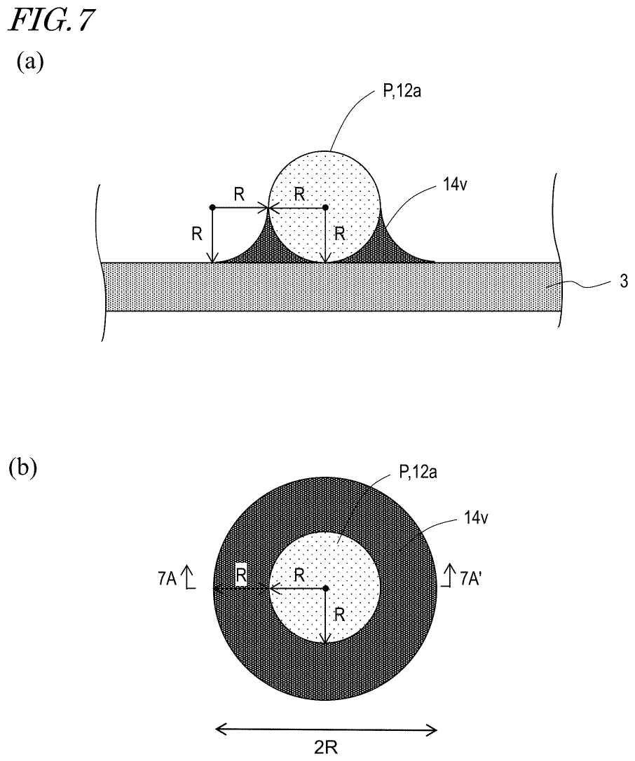

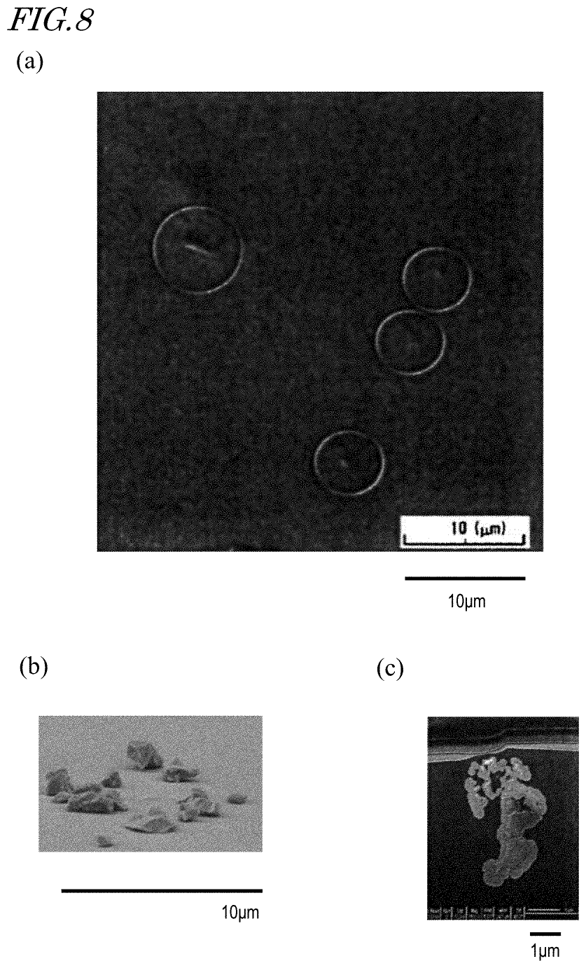

Now, with reference to FIG. 7(a) and FIG. 7(b), the volume of the organic barrier layer (solid portion) to be formed in the vicinity of the particle P and a preferred size of the microscopic liquid drops used to form the organic barrier layer will be described. FIG. 7(a) and FIG. 7(b) are schematic views provided to describe a preferred range of volume of the organic barrier layer to be formed in the vicinity of the particle P in the OLED display device according to an embodiment of the present invention. FIG. 7(a) is a cross-sectional view taken along line 7A-7A′ in FIG. 7(b), and is a schematic view of a cross-section including a diameter of the particle P. FIG. 7(b) is a plan view as seen in a direction normal to the surface of the OLED 3.

Now, it is assumed that the particle P or the first inorganic barrier layer 12a formed so as to cover the particle P (the particle P and the first inorganic barrier layer 12a formed so as to cover the particle P may be collectively referred to as a “convex portion by the particle P”) is spherical. An organic barrier layer 14v in the vicinity of the particle P may be formed to cover the particle P and/or the inorganic barrier layer 12a on the particle P. However, if the organic barrier layer 14 is too thick, the light that is output from an organic light emitting layer is disturbed by a refraction function (lens effect) or a scattering function of the organic barrier layer 14v, and as a result, may cause local display unevenness to deteriorate the display quality.

Therefore, in the case where the particle P has a shape close to a sphere, it is preferred that as shown in FIG. 7(a), the organic barrier layer 14v is formed only in a region extending downward by a length corresponding to the radius R from a position corresponding to the center of the convex portion by the particle P. The organic barrier layer 14v may be formed in this manner by adjusting the volume of the coating liquid to be supplied (in the case where the coating liquid contains a solvent, by adjusting the volume of the solid content) and/or by adjusting the ashing conditions (e.g., time). Ashing will be described below.

Assuming that a concave surface of the organic barrier layer 14v is a curved surface having a radius of curvature that is the same as the radius R of the convex portion by the particle P, the volume V₀ of the organic barrier layer 14v shown in FIG. 7(a) and FIG. 7(b) is represented by the following expression (1).

$${V}_{0} = ( 4 - π ) π {R}^{3} \qquad ( 1 )$$

When the radius R of the convex portion by the particle P is 0.15 μm, V₀ is about 0.009 fL. When the radius R is 0.25 μm, V₀ is about 0.04 fL. When the radius R is 2.5 μm, V₀ is about 42 fL.

It is preferred that the volume of the organic barrier layer 14v is larger than, or equal to, about ½ of V₀. If the volume of the organic barrier layer 14v is smaller than this range, there is an undesirable possibility that the effect of the formation of the organic barrier layer 14v is not supplied, namely, the second inorganic barrier layer 16 with a fine film with no defect is not formed. The upper limit of the volume of the organic barrier layer 14v may be a level at which the organic barrier layer 14v formed in the vicinity of the convex portion by the particle P does not cause local display unevenness. For example, the upper limit preferably does not exceed five times of V₀, and preferably does not exceed twice of V₀. In the case where the radius R of the convex portion by the particle P is shorter than 2.5 μm (in the case where V₀ is smaller than about 42 fL), the volume of the organic barrier layer 14v is not limited to the above-described range. The volume of the organic barrier layer 14v is merely required not to exceed about 200 fL, and is preferably smaller than, or equal to, about 100 fL.

It is preferred that the size of the microscopic liquid drops is appropriately set in accordance with the radius R of the convex portion by the particle P. It is preferred that, for example, the size of the microscopic liquid drops is set such that one to three drops satisfy V₀. A solvent may be incorporated into the coating liquid, so that the microscopic liquid drops are made large (to a size range from a size larger than the original size to 10 times the original size) with respect to the solid content in the coating liquid (amount remaining as the organic barrier layer 14v in a final state).

A convex portion, by the particle P, having a diameter shorter than 0.2 μm (having a radius R shorter than 0.1 μm) is considered to have substantially no influence on the moisture-resistance reliability even if the organic barrier layer 14v is not provided. Therefore, it is merely needed to detect convex portions, by the particle P, having a diameter of 0.2 μm or longer (having a radius R of 0.1 μm or longer) and form the organic barrier layer 14v in corresponding portions.

It is not efficient to supply a microscopic liquid drop of 0.1 fL (having a diameter of about 0.6 μm) a great number of times to a particle P having a diameter of 5 μm (having a radius R of 2.5 μm). Therefore, for example, an inkjet head generating microscopic liquid drops smaller than fL (having a diameter shorter than about 1.2 μm; for example, microscopic liquid drops of 1 fL), and an inkjet head generating microscopic liquid drops of 10 fL or larger and smaller than 0.5 pL (having a diameter of about 2.7 μm or longer and shorter than about 10 μm; for example, microscopic liquid drops of 50 fL), may be prepared. In this case, one of the inkjet heads may be selected in accordance with the size of the particle P. Needless to say, three or more inkjet heads generating microscopic liquid drops of different sizes may be prepared. For example, various inkjet heads may be prepared, such as an inkjet head for a size of 0.1 fL, an inkjet head for a size larger than 0.1 fL and smaller than 1 fL, an inkjet head for a size of 1 fL or larger and smaller than 10 fL, an inkjet head for a size of 10 fL or larger and smaller than 100 fL, an inkjet head for a size of 100 fL or larger and smaller than 0.5 pL, and the like. The smallest liquid drop generated by the inkjet device DIMATIX described in Patent Document No. 3 has a size of 1 pL (having a diameter of about 12 μm), which is too large. The UV irradiation head 56 is commonly usable.

In the above description, the particles are approximated to spheres in order to explain the relationship between the particles and the volumes of the microscopic liquid drops. In actuality, particles contain amorphous grains, for example, pieces of broken glass.

FIG. 8(a) through FIG. 8(c) each show a particle image found during the production of an OLED display device. FIG. 8(a) is an SEM image viewed from just above the element substrate by a scanning electron microscope SU-8020 (produced by Hitachi Hi-Tech Corporation). A particle is recognized in each of circles. In FIG. 8(a), the large particle at the top left has a lengthy shape having a length of about 3 μm and a width of about 0.2 μm. FIG. 8(b) is a perspective SEM image of grain-like particles viewed by a scanning electron microscope S-4700 (produced by Hitachi Hi-Tech Corporation). As can be seen from this SEM image, there are cube-like particles. The particles do not necessarily have a smooth surface, and may have a surface with microscopic concave portions and convex portions. FIG. 8(c) is a cross-sectional SEM image of a portion including a particle buried in a resin layer viewed by a scanning electron microscope S-4800 (produced by Hitachi Hi-Tech Corporation). As can be seen from this cross-sectional SEM image, even though appearing to be formed of one grain, one particle may be formed by cohesion of a plurality of microscopic grains. The “particles” in this specification encompasses a body of microscopic grains obtained by cohesion (secondary grains).

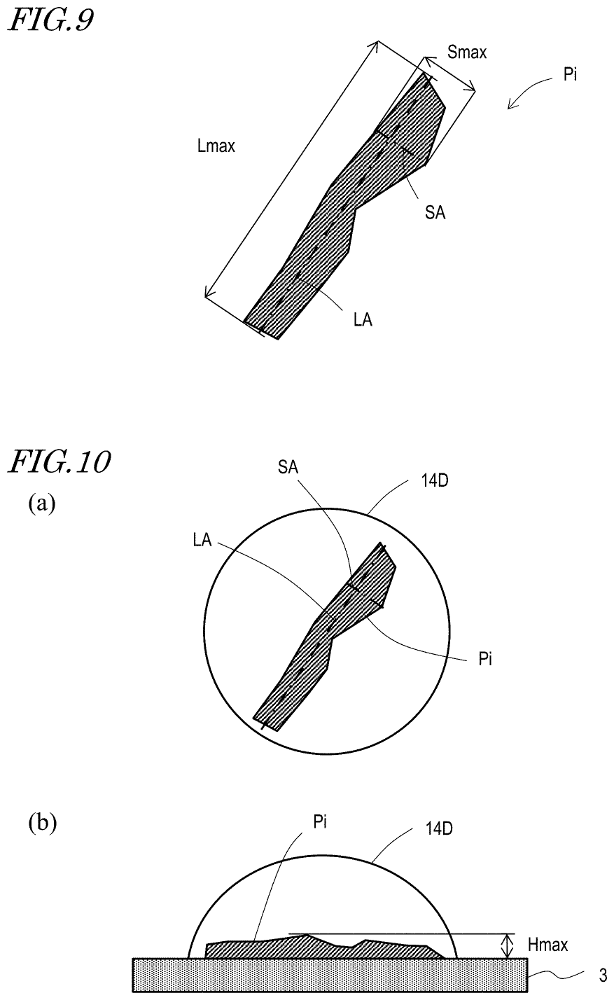

FIG. 9 is a schematic plan view of a lengthy particle Pi. This plan view corresponds to an image of the particle Pi acquired by a foreign object detection device (projected image). As described below, it is not preferred to approximate such a lengthy particle Pi to a sphere or a circle. The particle Pi (projected image thereof) has a longer axis LA having a maximum length Lmax and a shorter axis SA perpendicular to the longer axis LA and having a maximum length Smax. The aspect ratio Lmax/Smax is about 5.4. A maximum height Hmax is about 1/10 of Lmax (see FIG. 10(b)).

As can be seen, the longer axis LA of the lengthy particle Pi is longer than the diameter of a circle having a corresponding area-equivalent diameter. Therefore, even if being supplied with a microscopic liquid drop having the corresponding area-equivalent diameter, the particle Pi may undesirably not be covered sufficiently. The corresponding volume-equivalent diameter is still shorter than the corresponding area-equivalent diameter.

FIG. 10(a) and FIG. 10(b) are each a schematic view showing a state where the lengthy particle Pi is supplied with a microscopic liquid drop 14D having a diameter longer than the length of the longer axis LA. FIG. 10(a) is a plan view thereof, and FIG. 10(b) is a side view thereof. As can be seen from FIG. 10(a), the microscopic liquid drop 14D is excessive in the direction of the shorter axis SA of the particle Pi. As can be seen from FIG. 10(b), the microscopic liquid drop 14D has a height that is excessive for the height Hmax of the particle Pi. If the photocurable resin contained in the microscopic liquid drop 14D is cured in this state, the organic barrier layer becomes unnecessarily thick. As a result, the light that is output from the organic light emitting layer is disturbed by a refraction function (lens effect) or a scattering function of the organic barrier layer. As a result, local display unevenness is caused to deteriorate the display quality. In addition, the excessively thick organic barrier layer is likely to cause a fault in the formation of the second inorganic barrier layer, and thus declines the moisture-resistance reliability. Therefore, disadvantageously, there occurs a need to increase the thickness of the second inorganic barrier layer in order to cover the organic barrier layer with the second inorganic barrier layer with certainty.

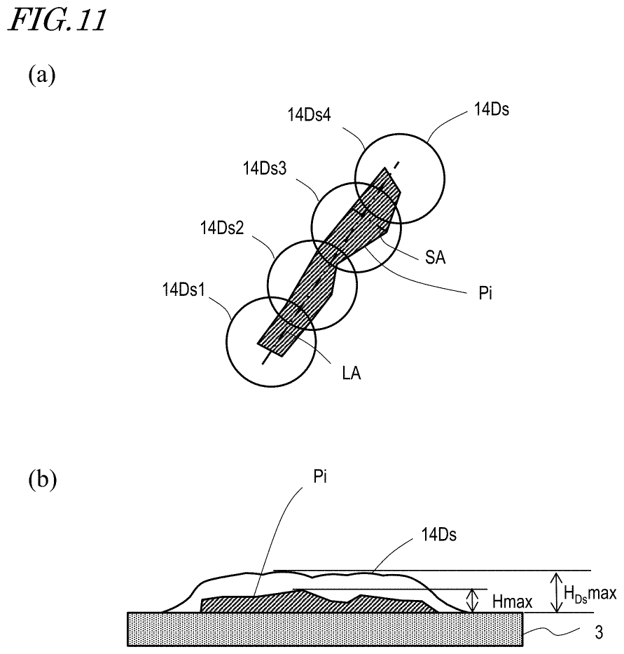

In such a situation, with a method for producing an organic EL device according to another embodiment of the present invention, as schematically shown in FIG. 11, the particle Pi is supplied with a first microscopic liquid drop 14Ds having a volume of 0.1 fL or larger and smaller than 10 fL at least twice along the longer axis LA of the particle Pi. FIG. 11 shows schematic views of a state where the lengthy particle Pi is supplied with the microscopic liquid drops 14Ds by an inkjet method by the method for producing an OLED display device according to an embodiment of the present invention. FIG. 11(a) is a plan view thereof, and FIG. 11(b) is a side view thereof. In this example, four microscopic liquid drops 14Ds1, 14Ds2, 14Ds3 and 14Ds4 are supplied generally on, and along, the longer axis LA of the particle Pi. The microscopic liquid drops 14Ds1, 14Ds2, 14Ds3 and 14Ds4 each have a volume of 0.1 fL or larger and smaller than 10 fL independently, and may have different volumes from each other. The volumes of the microscopic liquid drops 14Ds1, 14Ds2, 14Ds3 and 14Ds4 may be appropriately set in accordance with the shape of the particle Pi. The reference sign 14Ds refers to each of the microscopic liquid drops, and may also refer to the entirety of the coating liquid supplied as the microscopic liquid drops 14Ds1, 14Ds2, 14Ds3 and 14Ds4.

In this example, the four microscopic liquid drops 14Ds1, 14Ds2, 14Ds3 and 14Ds4 are supplied to the particle Pi. The embodiment of the present invention is not limited to this. It is sufficient that two or more microscopic liquid drops are supplied to the particle Pi along the longer axis LA thereof. It is preferred that each of the microscopic liquid drops 14Ds has a diameter longer than the length of the shorter axis SA of the particle Pi at the position where each of the microscopic liquid drops 14Ds is located. In this example, among the four microscopic liquid drops 14Ds1, 14Ds2, 14Ds3 and 14Ds4, each two microscopic liquid drops 14Ds adjacent to each other overlap each other (the distance between the centers of such two adjacent microscopic liquid drops is shorter than the sum of the radii of such two adjacent microscopic liquid drops). The embodiment of the present invention is not limited to this. Each two microscopic liquid drops 14Ds adjacent to each other may be separated from each other.

As is clear from the comparison between FIG. 10 and FIG. 11, in the case where two or more microscopic liquid drops 14Ds are supplied to the particle Pi along the longer axis LA thereof, the total volume of the microscopic liquid drops 14Ds covering the particle Pi is decreased, the distance by which the microscopic liquid drops 14Ds protrude from the particle Pi in the direction of the shorter axis SA is shortened, and the height of the microscopic liquid drops 14Ds is decreased as represented by H_{Ds}max. Therefore, an unnecessarily thick organic barrier layer is not formed, unlike in the case described above with reference to FIG. 10. Thus, the problems of the local display unevenness and the like are suppressed.

In the above example, the particle Pi having an aspect ratio of about 5 is described. This embodiment is not limited to this, needless to say. A particle Pi having an aspect ratio of 3 or larger may be supplied with a microscopic liquid drop at least twice along a longer axis thereof. Needless to say, a particle Pi having an aspect ratio of 2 or larger may be supplied with a microscopic liquid drop at least twice along a longer axis thereof.

In the example shown in FIG. 11, the microscopic liquid drops are supplied to the particle Pi generally on, and along, the longer axis thereof. The direction in which the microscopic liquid drops are supplied is not limited to this. In the case where, for example, the particle Pi is relatively large and the width of the particle Pi significantly changes along the longer axis thereof, the microscopic liquid drop may be supplied to the particle Pi at least twice on the contour thereof, along the longer axis thereof. In this case, contour information on the particle Pi is found in advance as the shape information.

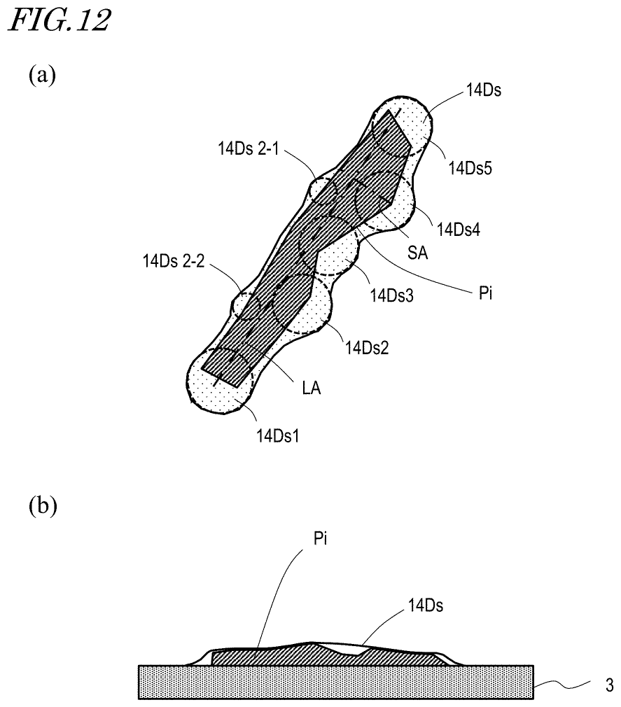

FIG. 12 shows schematic views of another state where the lengthy particle Pi is supplied with the microscopic liquid drops 14Ds by an inkjet method by the method for producing an OLED display device according to an embodiment of the present invention. FIG. 12(a) is a plan view thereof, and FIG. 12(b) is a side view thereof. In the case where as shown in FIG. 12, the width of the particle Pi significantly changes along the longer axis LA, microscopic liquid drops 14Ds1, 14Ds2, 14Ds3, 14Ds4 and 14Ds5 may be supplied to the particle Pi on the contour thereof, along the longer axis LA thereof. In this case, the microscopic liquid drops 14Ds1, 14Ds2, 14Ds3, 14Ds4 and 14Ds5 may be separated from each other. The microscopic liquid drops 14Ds1, 14Ds2, 14Ds3, 14Ds4 and 14Ds5 may have different sizes (diameters) from each other independently.

The coating liquid 14Ds supplied as the microscopic liquid drops 14Ds1, 14Ds2, 14Ds3, 14Ds4 and 14Ds5 spreads while being wet on a surface of the particle Pi and the surface of the element substrate 3 (i.e., on a surface of the first inorganic barrier layer 12). At this point, the coating liquid 14Ds spreads along a periphery of the particle Pi by a capillary action. As a result, as shown in FIG. 12(b), steps formed in the vicinity of the particle Pi may be buried with the coating liquid 14Ds having a continuously smooth surface (concave surface). The photocurable resin contained in the coating liquid 14Ds in this state is cured, so that the organic barrier layer 14 having a continuously smooth surface is obtained. The microscopic liquid drops 14Ds are supplied in this manner, and thus the amount of the coating liquid may be further decreased.

As shown in FIG. 12(a), microscopic liquid drops 14D2-1 and 14D2-2 may also be supplied to generally straight portions of the contour of the particle Pi when necessary. Each of the microscopic liquid drops 14D2-1 and 14D2-2 may be smaller than each of the microscopic liquid drops 14Ds1, 14Ds2, 14Ds3, 14Ds4 and 14Ds5.

As described above, in the case where two or more microscopic liquid drops 14Ds are supplied, each two microscopic liquid drops 14Ds adjacent to each other may be separated from each other. In the case where the particle Pi is small, it is sufficient to provide, once, a first microscopic liquid drop having a volume of 0.1 fL or larger and smaller than 10 fL and having a diameter shorter than the length of the longer axis of a first particle. Even in this case, the microscopic liquid drop spreads along the periphery of the particle Pi by a capillary action, and thus may cover the particle Pi effectively.

As described above, in the case where the particle cannot be approximated to a sphere as described above, it is sufficient that at least a discontinuous portion between the convex portion (protruding portion) and the concave portion of the particle is smoothly filled with the organic barrier layer. For example, in the case of a grain-like (cubic) particle, it is preferred that the organic barrier layer is formed so as to cover the convex portion. In the case of a particle having concave and convex portions at the surface thereof, it is preferred that the organic barrier layer is formed so as to fill the concave and convex portions. In the case of such a particle that is not spherical, the entirety of the particle may be covered with the organic barrier layer. It is preferred that the volume of the organic barrier layer does not exceed five times the volume of the particle, and it is more preferred that the volume of the organic barrier layer does not exceed twice the volume of the particle.

The method for producing an organic EL device according to this embodiment may be carried out by use of the foreign object detection device and the inkjet device described above.

First, the particles located below or above the first inorganic barrier layer and each having an area-equivalent diameter of 0.2 μm or longer and 5 μm or shorter are detected, and position information, size information and shape information on each of the detected particles are found. For each of particles having an area-equivalent diameter of 1 μm or longer, the aspect ratio is found. The size of the particles, for which the aspect ratio is to be found, is appropriately set. For example, it may be set such that the aspect ratio is to be found for particles each having an area-equivalent diameter of 0.5 μm or longer. Regarding a particle having an area-equivalent diameter shorter than 0.5 μm, there is no significant advantage of moving the particle in the direction of the longer axis thereof to be supplied with the microscopic liquid drops even if the particle has an aspect ratio of 2 or larger.

The foreign object detection device extracts an image of a particle (corresponding to the projected image) from an image of the surface of the element substrate acquired by, for example, an image sensor (e.g., CCD). This is performed by comparing, for example, a reference image and the acquired image against each other. The position information, the size information, the shape information and the like on each of the detected particles are also found and stored.

The aspect ratio may be found by any of various types of known image processing software. For example, a rectangle to which the image of the particle (contour) is inscribed is found, and the position information and the lengths of the longer side and the shorter side thereof are found. The aspect ratio is found by “length of the longer side/length of the shorter side”.

Alternatively, the length may be found from the image of the particle (contour). First, from the image of the particle (contour), the longer axis LA having a maximum length Lmax is found. Next, the particle is sequentially scanned in the direction perpendicular to the longer axis LA to find the lengths of the particle in the direction of the shorter axis. From the found lengths of the particle in the direction of the shorter axis, the shorter axis SA having a maximum length Smax is found. From Lmax and Smax thus obtained, the aspect ratio Lmax/Smax is found.

The foreign object detection device may also find parameters such as the area-equivalent diameter, the volume-equivalent diameter and the like of the particle by use of a known image processing program. Such information is stored as being associated with the position information and the like on each of the particles.

The information on each of the particles is used, such that for a particle having an area-equivalent diameter of 1 μm or longer and an aspect ratio of 3 or larger, an inkjet nozzle that ejects microscopic liquid drops having a volume of 0.1 fL or larger and smaller than 10 fL is selected. Such a microscopic liquid drop is supplied at least twice along the longer axis of the particle. It is preferred that the smallest microscopic liquid drop has a volume of 1 fL or smaller. These criteria may be changed appropriately. For example, the above-described inkjet nozzle may be selected for a particle having an aspect ratio of 2 or larger. The length Lmax of the longer axis may be used instead of the area-equivalent diameter, and the above-described inkjet nozzle may be selected for a particle having a longer axis of a length Lmax of, for example, 1 μm or longer. Alternatively, the length Smax of the shorter axis may be used, and the above-described inkjet nozzle may be selected for a particle having a shorter axis of a length Smax of, for example, 0.2 μm or longer. There may be particles having a very large aspect ratio, but the aspect ratio is generally 5 μm/0.2 μm (=25) at the maximum.

For, among the particles each having an aspect ratio smaller than 2, particles each having an area-equivalent diameter of 5 μm, microscopic liquid drops larger than those described above, for example, microscopic liquid drops having a volume of 10 fL or larger, may be used. There is no specific upper limit on the volume of the microscopic liquid drops usable for such a particle. For example, the volume of the microscopic liquid drops is 0.5 pL or smaller. Needless to say, the microscopic liquid drops larger than those described above, for example, the microscopic liquid drops having a volume of 10 fL or larger, are not limited to being used for a particle having an area-equivalent diameter of 5 μm. Such microscopic liquid drops may be used for particles each having an area-equivalent diameter of 3 μm or longer. These criteria may be changed appropriately. For example, the length Lmax of the longer axis may be used instead of the area-equivalent diameter, and the above-described microscopic liquid drops may be used for particles each having a longer axis of a length Lmax of, for example, 3 μm or longer. Alternatively, the length Smax of the shorter axis may be used, and the above-described microscopic liquid drops may be used for particles each having a shorter axis of a length Smax of, for example, 0.5 μm or longer.

A coating liquid containing a photocurable resin (monomer) may contain a photoinitiator (radical polymerization initiator or cationic polymerization initiator) and also a small amount of additive such as a surfactant or the like. The photocurable resin is contained in the coating liquid at a content of about 80% by mass to about 90% by mass, and the photoinitiator is contained at a content of about 5% by mass to about 10% by mass. A pigment or a dye may be incorporated into the coating liquid. In the case where a pigment is incorporated, a dispersant may also be incorporated. A preferred viscosity is, for example, about 0.5 mPa-s or higher and 10 Pa-s. In the case where a dye or a pigment is incorporated, it is easily checked whether or not the organic barrier layer (solid portion) has been formed at a desired position. The relatively thick organic barrier layer may undesirably decline the display quality by the lens effect or the like. In order to suppress this, it is preferred that, for example, a pigment or a dye that absorbs or attenuates light is incorporated into the microscopic liquid drops of 10 fL or larger. In this case, the pigment needs to be put into microscopic pieces, which raises the viscosity. Therefore, it is more preferred to use a dye. In the case where, for example, microscopic liquid drops of 1 fL or smaller, especially, microscopic liquid drops of 0.1 fL, are to be generated, it is preferred that the coating liquid does not contain a pigment or a dye. In order to adjust the viscosity of the coating liquid or the size (volume) of the microscopic liquid drops, a solvent (e.g., an organic solvent such as alcohol or the like) may be incorporated.

Usable as the photocurable resin may be a radical polymerizable monomer containing a vinyl group such as an acrylic resin (acrylate monomer) or the like, or a cationic polymerizable monomer containing an epoxy group. An appropriate photoinitiator is selected in accordance with the type of the resin to be used and the wavelength range of the UV light to be directed. Instead of the UV irradiation head 56, an ultraviolet irradiation device such as a high pressure mercury lamp, a super-high pressure mercury lamp or the like may be used to, for example, irradiate the entirety of the photocurable resin on the substrate 100M with ultraviolet rays at the same time.

The production method may further include a step of partially ashing the photocured resin layer formed by curing the photocurable resin. Ashing may be performed by use of a known plasma ashing device, a known ashing device using corona discharge, a known photo-excited ashing device, or a known UV ozone ashing device. Ashing may be performed, for example, by plasma ashing using at least one type of gas among N₂O, O₂ and O₃, or by a combination of plasma ashing and ultraviolet irradiation. In the case where an SiN film is formed by CVD as each of the first inorganic barrier layer 12 and the second inorganic barrier layer 16, N₂O is used as material gas. Therefore, use of N₂O for ashing provides an advantage of simplifying the ashing device.

Ashing results in oxidizing the surface the organic barrier layer 14 to modify the surface of the organic barrier layer 14 to be hydrophilic. In addition, ashing results in shaving the surface the organic barrier layer 14 substantially uniformly and forming extremely tiny concaved and convexed portions to increase the surface area size of the organic barrier layer 14. The effect of ashing of increasing the surface area size is greater for the surface of the organic barrier layer 14 than for the surface of the first inorganic barrier layer 12 formed of an inorganic material. Since the surface of the organic barrier layer 14 is modified to be hydrophilic and the surface area size thereof is increased, the adhesiveness between the organic barrier layer 14 and the second inorganic barrier layer 16 is improved.

Ashing results in, for example, removing the photocured resin layer formed on the convex portion by the particle P to adjust the location and/or the volume of the organic barrier layer 14 remaining in a final state, and also results in improving the adhesiveness between the organic barrier layer 14 and the second inorganic barrier layer 16.

In order to improve the adhesiveness and/or the wettability between the first inorganic barrier layer 12 and the organic barrier layer 14, the surface of the first inorganic barrier layer 12 may be ashed before the organic barrier layer 14 is formed. In FIG. 11(b) and FIG. 12(b), the coating liquid supplied as the microscopic liquid drops 14Ds forms a concave surface facing the surface of the element substrate 3, namely, the surface of the first inorganic barrier layer 12, and provides a preferred level of wettability. In the case where the wettability of the surface of the inorganic barrier layer 12 or the particle Pi with respect to the coating liquid is low, the surface of the element substrate 3 (i.e., the surface of the inorganic barrier layer 12 and the surface of the particle Pi) may be ashed before the microscopic liquid drops 14Ds are supplied, so that the wettability is improved.

Embodiments of a method for producing an OLED display device including a flexible substrate, and such an OLED display device are described above. The embodiments of the present invention are not limited to the embodiments described above as examples. The embodiments of the present invention are widely applicable to an organic EL device including an organic EL element formed on a non-flexible substrate (e.g., glass substrate) and a thin film encapsulation structure formed on the organic EL element (applicable to, for example, an organic EL illumination device). For example, in the case where an embodiment of the present invention is applied to an organic EL illumination device, the problems that the reliability is declined and that the luminous intensity distribution characteristics are declined due to uneven luminance are suppressed.

### INDUSTRIAL APPLICABILITY

Embodiments of the present invention are applicable to a method for producing an organic EL device. The embodiments of the present invention are especially preferably applicable to a method for producing a flexible organic EL display device.

### REFERENCE SIGNS LIST

10 TFE structure
12, 12a, 12b first inorganic barrier layer (SiN layer)
14 organic barrier layer
14Ds microscopic liquid drop (coating liquid)
16 second inorganic barrier layer
40 foreign object detection device
42 controller
44 detection head
50 inkjet device
52 controller
54 inkjet head
56 UV irradiation head

1-8. (canceled)

9. A method for producing an organic electroluminescent device, comprising the steps of:
preparing an element substrate including a substrate and a plurality of organic electroluminescent elements supported by the substrate; and
forming a thin film encapsulation structure covering the plurality of organic electroluminescent elements,
wherein the step of forming the thin film encapsulation structure includes:
step A of forming a first inorganic barrier layer,
step B of, after the step A, detecting particles located below or above the first inorganic barrier layer and each having an area-equivalent diameter of 0.2 μm or longer and 5 μm or shorter, and finding position information, size information and shape information on each of the detected particles and finding an aspect ratio of each of particles, among the detected particles, having an area-equivalent diameter of 1 μm or longer,
step C of supplying each of the particles with a microscopic liquid drop(s) of a coating liquid containing a photocurable resin by an inkjet method based on the position information,
step D of, after the step C, irradiating the photocurable resin with ultraviolet rays and thus curing the photocurable resin to form an organic barrier layer, and
step E of, after the step D, forming a second inorganic barrier layer on the first inorganic barrier layer and the organic barrier layer, and
wherein the step C includes the step of supplying each of first particles each having an aspect ratio of 3 or larger, among the particles, with a first microscopic liquid drop having a volume of 0.1 fL or larger and smaller than 10 fL at least twice along a longer axis of the first particle.

10. The method of claim 9, wherein in the step C, the microscopic liquid drops include a second microscopic liquid drop having a size larger than that of the first microscopic liquid drop; and the step C includes the step of selecting the first microscopic liquid drop for the first particle, and selecting the second microscopic liquid drop for, among second particles each having an aspect ratio smaller than 2, at least each of particles having an area-equivalent diameter of 5 μm, based on the size information on each of the particles.

11. The method of claim 10, wherein the first microscopic liquid drop does not contain a dye or a pigment, and the second microscopic liquid drop contains a dye or a pigment.

12. The method of claim 10, wherein the second microscopic liquid drop has a volume of 10 fL or larger and 0.5 pL or smaller.

13. The method of claim 9, wherein the first microscopic liquid drop has a volume of 1 fL or smaller.

14. The method of claim 9, wherein the step D further includes the step of partially ashing a photocured resin layer formed by curing the photocurable resin.

15. The method of claim 9, further comprising the step of, before the step C, ashing a surface of the first inorganic barrier layer.

16. A method for producing an organic electroluminescent device, comprising the steps of:
preparing an element substrate including a substrate and a plurality of organic electroluminescent elements supported by the substrate; and
forming a thin film encapsulation structure covering the plurality of organic electroluminescent elements,
wherein the step of forming the thin film encapsulation structure includes:
step A of forming a first inorganic barrier layer,
step B of, after the step A, detecting particles located below or above the first inorganic barrier layer and each having an area-equivalent diameter of 0.2 μm or longer and 5 μm or shorter, and finding position information, size information and shape information on each of the detected particles and finding an aspect ratio of each of particles, among the detected particles, having an area-equivalent diameter of 1 μm or longer,
step C of supplying each of the particles with a microscopic liquid drop(s) of a coating liquid containing a photocurable resin by an inkjet method based on the position information,
step D of, after the step C, irradiating the photocurable resin with ultraviolet rays and thus curing the photocurable resin to form an organic barrier layer, and
step E of, after the step D, forming a second inorganic barrier layer on the first inorganic barrier layer and the organic barrier layer, and
wherein the step C includes the step of supplying each of first particles each having an aspect ratio of 3 or larger, among the particles, with a first microscopic liquid drop having a volume of 0.1 fL or larger and smaller than 10 fL and having a diameter shorter than a length of a longer axis of the first particle at least twice.

17. The method of claim 16, wherein in the step C, the microscopic liquid drops include a second microscopic liquid drop having a size larger than that of the first microscopic liquid drop; and the step C includes the step of selecting the first microscopic liquid drop for the first particle, and selecting the second microscopic liquid drop for, among second particles each having an aspect ratio smaller than 2, at least each of particles having an area-equivalent diameter of 5 μm, based on the size information on each of the particles.

18. The method of claim 17, wherein the first microscopic liquid drop does not contain a dye or a pigment, and the second microscopic liquid drop contains a dye or a pigment.

19. The method of claim 17, wherein the second microscopic liquid drop has a volume of 10 fL or larger and 0.5 pL or smaller.

20. The method of claim 16, wherein the first microscopic liquid drop has a volume of 1 fL or smaller.

21. The method of claim 16, wherein the step D further includes the step of partially ashing a photocured resin layer formed by curing the photocurable resin.

22. The method of claim 16, further comprising the step of, before the step C, ashing a surface of the first inorganic barrier layer.
